(19) United States
(12) Patent Application Publication
(10) Pub. No.: US 2025/0234722 A1
(43) Pub. Date: Jul. 17, 2025

(54) DISPLAY DEVICE

(71) Applicant: Samsung Display Co., LTD., Yongin-si (KR)

(72) Inventors: Yun Jee PARK, Yongin-si (KR); Jae Bum HAN, Yongin-si (KR)

(73) Assignee: Samsung Display Co., LTD., Yongin-si (KR)

(21) Appl. No.: 18/810,946

(22) Filed: Aug. 21, 2024

(30) Foreign Application Priority Data
Jan. 11, 2024 (KR) 10-2024-0004774

(51) Int. Cl. H10K 59/124

(52) U.S. Cl. CPC H10K 59/124

(57) ABSTRACT

A display device includes a first insulating layer disposed on a substrate, a first transistor including a first active layer on the first insulating layer and having a first mobility, and a first gate electrode overlapping the first active layer, a first gate insulating layer on the first insulating layer and the first active layer, a second gate insulating layer on the first gate insulating layer, and a second transistor including a second active layer between the first gate insulating layer and the second gate insulating layer, spaced apart from the first active layer and having a second mobility greater than the first mobility, and a second gate electrode overlapping the second active layer. The first gate insulating layer includes a first oxide layer, a nitride layer, and a second oxide layer with lower hydrogen concentration than the first oxide layer.

### CROSS REFERENCE TO RELATED APPLICATION(S)

This application claims priority to and benefits of Korean Patent Application No. 10-2024-0004774 under 35 USC § 119, filed on Jan. 11, 2024, in the Korean Intellectual Property Office (KIPO), the entire contents of which are incorporated herein by reference.

### BACKGROUND

### 1. Technical Field

Embodiments of the disclosure relate to a display device.

### 2. Description of the Related Art

As the information-oriented society evolves, various demands for display devices are ever increasing. Accordingly, a variety of types of display devices, including light-emitting display devices, are under development. A light-emitting display device may include pixels including transistors and light-emitting elements.

### SUMMARY

Aspects of the disclosure provide a display device that can improve the operating characteristics of pixels.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an embodiment of the disclosure, a display device may include a first insulating layer disposed on a substrate, a first transistor including a first active layer disposed on the first insulating layer and having a first mobility, and a first gate electrode overlapping the first active layer in a plan view, a first gate insulating layer disposed on the first insulating layer and the first active layer, a second gate insulating layer disposed on the first gate insulating layer, and a second transistor including a second active layer disposed between the first gate insulating layer and the second gate insulating layer at a position spaced apart from the first active layer and having a second mobility greater than the first mobility, and a second gate electrode overlapping the second active layer in a plan view. The first gate insulating layer may include a first oxide layer, a nitride layer on the first oxide layer, and a second oxide layer on the nitride layer, and a hydrogen concentration of the first oxide layer may be higher than a hydrogen concentration of the second oxide layer.

In an embodiment, the first active layer may include a first oxide semiconductor, and the second active layer may include a second oxide semiconductor different from the first oxide semiconductor.

In an embodiment, the first oxide semiconductor may include indium-gallium-zinc oxide (IGZO).

In an embodiment, the second oxide semiconductor may include indium-tin-gallium-zinc oxide (ITGZO) or indium-gallium oxide (IGO).

In an embodiment, the first oxide layer and the second oxide layer may include silicon oxide.

In an embodiment, the nitride layer may include silicon nitride.

In an embodiment, the first gate insulating layer may include a first portion disposed on the first active layer, and a second portion disposed between the first insulating layer and the second active layer.

In an embodiment, the first gate insulating layer may be partially disposed on a portion of the first active layer and a portion of the first insulating layer.

In an embodiment, the second gate insulating layer may include a first portion disposed on the first portion of the first gate insulating layer, and a second portion disposed on the second active layer.

In an embodiment, the second gate insulating layer may be partially disposed on a portion of the first active layer and a portion of the second active layer.

In an embodiment, the first gate electrode and the second gate electrode may be disposed on the second gate insulating layer.

In an embodiment, the second gate insulating layer may include silicon oxide.

In an embodiment, the substrate may include a display area, and the first transistor and the second transistor are disposed in the display area.

In an embodiment, the display device may further include a pixel disposed in the display area and including the first transistor and the second transistor.

In an embodiment, the first transistor may be a driving transistor of the pixel.

In an embodiment, the pixel may further include a light-emitting element electrically connected to the first transistor.

In an embodiment, the display device may further include, a bottom electrode disposed between the substrate and the first insulating layer and overlapping the first active layer in a plan view.

In an embodiment, the second transistor may be a switching transistor of the pixel.

In an embodiment, the display device may further include a second insulating layer that is disposed on the first insulating layer and covers the first active layer, the first gate insulating layer, the second active layer, the second gate insulating layer, the first gate electrode, and the second gate electrode.

In an embodiment, the display device may further include at least one of a first source electrode disposed on the second insulating layer and electrically connected to a source region of the first active layer, a first drain electrode disposed on the second insulating layer and electrically connected to a drain region of the first active layer, a second source electrode disposed on the second insulating layer and electrically connected to a source region of the second active layer, and a second drain electrode disposed on the second insulating layer and electrically connected to a drain region of the second active layer.

According to embodiments of the disclosure, a display device may include a first gate insulating layer that is disposed on a first active layer of a first transistor disposed in a pixel and under a second active layer of a second transistor disposed in the pixel. The first gate insulating layer may be formed of three or more multiple layers including a first oxide layer, a nitride layer on the first oxide layer, and a second oxide layer on the nitride layer. The first oxide layer and the second oxide layer may have a hydrogen concentration suitable for improving and/or stabilizing the characteristics of the first transistor and the second transistor, respectively, and may have different hydrogen concentrations.

According to the embodiments, the characteristics of the first transistor and the second transistor may be simultaneously improved to meet the operating characteristics required for the first transistor and the second transistor of the pixel. Accordingly, the operating characteristics of the pixel including the first transistor and the second transistor and the display device including the pixel may be improved and the reliability of the pixel and the display device may be ensured.

However, effects according to the embodiments of the disclosure are not limited to those exemplified above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a plan view showing a display device according to an embodiment of the disclosure.

FIG. 2 is a plan view showing the display panel of FIG. 1.

FIG. 3 is a schematic diagram of an equivalent circuit of a pixel according to an embodiment of the disclosure.

FIG. 4 is a schematic cross-sectional view showing a display panel according to an embodiment of the disclosure.

FIG. 5 is a schematic cross-sectional view showing area A1 of FIG. 4 in detail.

FIG. 6 is a schematic cross-sectional view showing area A2 of FIG. 4 in detail.

### DETAILED DESCRIPTION OF THE EMBODIMENTS

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

Features of each of various embodiments of the disclosure may be partially or entirely combined with each other and may technically variously interwork with each other, and respective embodiments may be implemented independently of each other or may be implemented together in association with each other.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure will be described in detail with reference to the accompanying drawings.

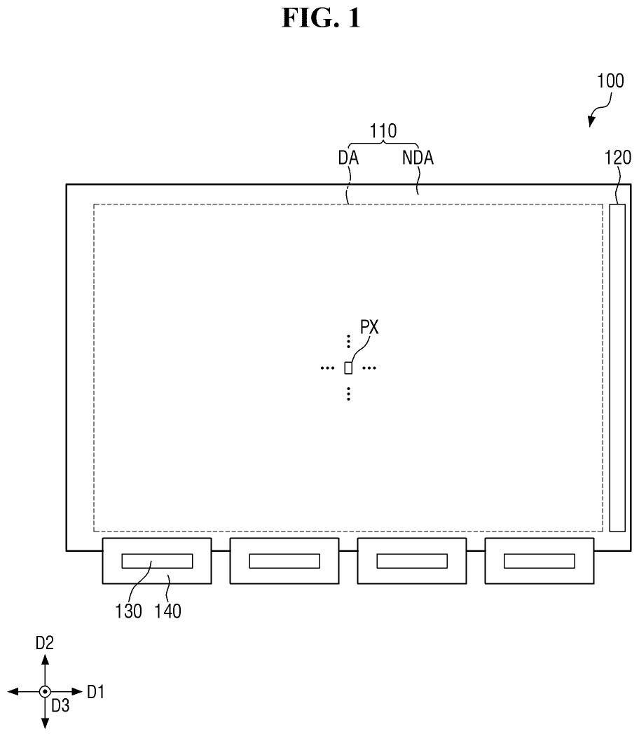

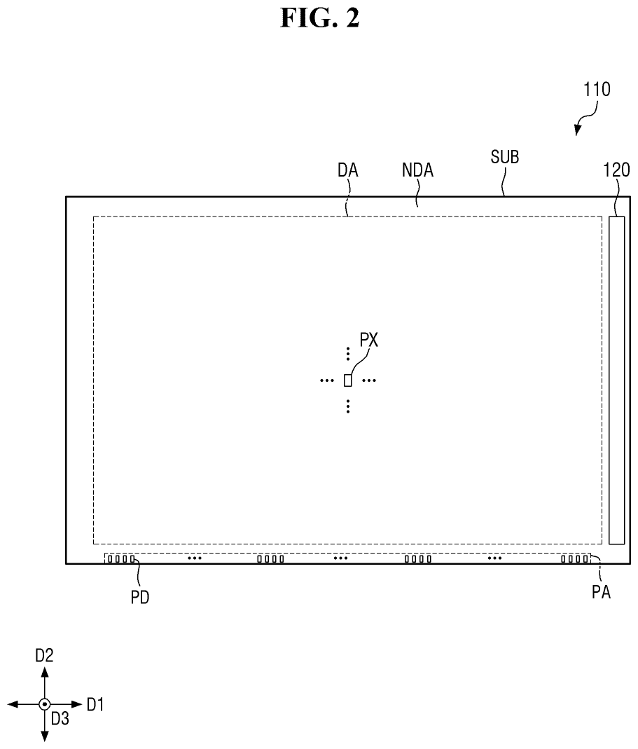

FIG. 1 is a plan view showing a display device 100 according to an embodiment of the disclosure. FIG. 2 is a plan view showing a display panel 110 of FIG. 1.

Referring to FIGS. 1 to 2, a display device 100 may be for displaying moving images or still images. The display device 1 may be used as a display screen of portable electronic devices such as a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), as well as a display screen of various products such as a television, a notebook, a monitor, a billboard and the Internet of Things (IoT). Those listed-above are merely examples, and the display device 100 may be employed in other electronic devices as well.

According to an embodiment of the disclosure, the display device 100 may be a light-emitting display device such as an organic light-emitting display device including organic light-emitting diodes, a quantum-dot light-emitting display device including quantum-dot light-emitting layer, and an ultra-small light-emitting display device including ultra-small light-emitting diodes such as micro or nano light-emitting diodes (micro LEDs or nano LEDs). It should be understood, however, that the disclosure is not limited thereto. For example, the display device 100 may be other types of display devices than light-emitting display devices. In the following description, a light-emitting display device (e.g., an organic light-emitting display device) is disclosed as an embodiment of the display device 100.

The display device 100 may include a display panel 110 including pixels PX, and a first driver 120 and second drivers 130 that supply driving signals to the pixels PX. The display device 100 may further include additional elements. For example, the display device 100 may further include a power supply unit for supplying supply voltages to the pixels PX, the first driver 120 and the second drivers 130, and a timing controller for controlling the operation of the first driver 120 and the second drivers 130, etc.

The display panel 110 may include a display area DA and a non-display area NDA. The display area DA may include pixels PX to display images. For example, the display area DA may include pixel areas where the pixels PX are disposed. The non-display area NDA may be an area other than the display area DA, where no image is displayed. According to an embodiment of the disclosure, the non-display area NDA may be disposed adjacent to (e.g., surround) the display area DA.

In FIGS. 1 and 2, a first direction D1, a second direction D2 and a third direction D3 are defined. According to an embodiment of the disclosure, the first direction D1 may be a horizontal direction of the display panel 110, and the second direction D2 may be a vertical direction of the display panel 110. The third direction D3 may be a thickness direction of the display panel 110.

According to an embodiment of the disclosure, the display panel 110 may have a rectangular shape in a plan view. Although the display panel 110 has the horizontal length greater than the vertical length in FIGS. 1 and 2, the shape of the display panel 110 is not limited thereto. For example, the display panel 110 may have a shape in which the vertical length is greater than the horizontal length, or may have a square shape, etc. The display panel 110 may include sharp corners or rounded corners.

The shape of the display panel 110 in a plan view is not limited to the above-described rectangular shapes but other shapes may be employed. For example, the display panel 110 may have a polygonal shape other than a rectangle, a circular shape, an elliptical shape, or other shapes.

The display panel 110 may be a rigid display panel that is not substantially deformable, or a flexible display panel that can be deformed, i.e., at least partially foldable, bendable or rollable. The display panel 110 may be provided to the display device 100 without being bent or with being partially bent.

The display panel 110 may include a substrate SUB and pixels PX disposed on the substrate SUB. The pixels PX may be disposed in the display area DA on the substrate SUB.

The substrate SUB may be a base member for fabricating or providing the display panel 110 and may form a base surface of the display panel 110. The substrate SUB may include the display area DA and the non-display area NDA surrounding the display area DA.

The display area DA may have a variety of shapes according to embodiments. For example, the display area DA may have a rectangular shape, a non-rectangular polygonal shape, a circular shape, an elliptical shape, an irregular shape, or other shapes in a plan view. According to an embodiment of the disclosure, the display area DA may have a shape that conforms to the shape of the display panel 110.

Multiple pixels PX may be arranged in the display area DA. For example, the display area DA may include pixel areas where the pixels PX are disposed.

According to an embodiment of the disclosure, the display device 100 may be a light-emitting display device, and each of the pixels PX may include a light-emitting element located in the respective emission area and a pixel circuit connected to the light-emitting element. In the following description of the embodiments, the term “connection” may encompass electrical connection and/or physical connection. Each of the pixel circuits may include transistors (e.g., a driving transistor that generates a driving current corresponding to a data signal, and at least one switching transistor), and at least one capacitor (e.g., a storage capacitor).

The non-display area NDA may include a pad area PA where pads PD are disposed. According to an embodiment of the disclosure, the non-display area NDA may further include a driver circuit area located on at least one side of the display area DA. At least one driver, pads PD and/or lines may be disposed in the non-display area NDA.

At least one driver for driving the pixels PX or a part of the driver may be disposed in the driver circuit area. For example, circuit elements forming the first driver 120 (e.g., driver transistors and driver capacitors forming stage circuits of the first driver 120) may be disposed in the driver circuit area on the substrate SUB. According to an embodiment of the disclosure, the circuit elements of the first driver 120 may be formed in the display panel 110 together with the pixels PX. According to an embodiment of the disclosure, the driver transistors provided to the first driver 120 may be transistors of substantially the same or similar type and/or structure as the transistors provided to the pixels PX, and may be formed together with transistors of the pixels PX. For example, each of the driver transistors may have a structure that is substantially the same as or similar to the driving transistors or switching transistors of the pixels PX.

Pads PD may be disposed in the pad area PA. At least one circuit board 140 may be disposed and/or bonded on the pad area PA. According to an embodiment of the disclosure, multiple circuit boards 140 connected to different pads PD may be disposed on the pad area PA. The pads PD may include signal pads and power pads for transmitting the driving signals and the supply voltages required for driving the pixels PX and/or the first driver 120 to the display panel 110.

The first driver 120 and the second drivers 130 may generate driving signals for controlling the operation timing and brightness of the pixels PX, and may supply the driving signals to the pixels PX. For example, the first driver 120 may be a gate driver including a scan driver, and may be connected to the pixels PX through the respective gate lines. The first driver 120 may supply gate signals (e.g., gate signals that control the operation timing of the pixels PX, including scan signals) to the pixels PX. The second drivers 130 may be data drivers including source driver circuits and may be connected to the pixels PX through the respective data lines. The second drivers 130 may supply the respective data signals to the pixels PX.

According to an embodiment of the disclosure, at least one of the first driver 120 and the second drivers 130 or a part of the at least one of the first driver 120 and the second drivers 130 may be incorporated into the display panel 110. For example, the first driver 120 or a part of the first driver 120 may be disposed on the substrate SUB of the display panel 110 and may be disposed and/or formed in the non-display area NDA.

Although the first driver 120 is formed on a side of the display area DA (for example, in the non-display area NDA on the right side of the display area DA) in the embodiment shown in FIG. 1, the disclosure is not limited thereto. In another embodiment, the first driver 120 may be located only on another side of the display area DA (for example, in the non-display area NDA on the left side of the display area DA), or located on both sides of the display area DA (for example, in the non-display area NDA on the left and right sides of the display area DA). In another embodiment, a part of the first driver 120 may be located in the non-display area NDA, while another part of the first driver 120 may be located in a non-emission area (for example, an area between the emission areas of the pixels PX) in the display area DA.

According to an embodiment of the disclosure, another one of the first driver 120 and the second drivers 130 or a part of the another one of the first driver 120 and the second drivers 130 may be disposed or formed outside the display panel 110 and may be electrically connected to the display panel 110. For example, the second drivers 130 may be implemented with multiple integrated circuit chips and may be disposed on circuit boards 140 electrically connected to the pixels PX of the display panel 110. The second drivers 130 may be implemented as at least one integrated circuit chip and may be mounted on the non-display area NDA of the display panel 110.

The circuit board 140 may be connected to the display panel 110 through the pads PD. According to an embodiment of the disclosure, the circuit board 140 may be, but is not limited to, a flexible printed circuit board (FPCB), a printed circuit board (PCB) or a flexible film such as chip on film (COF). According to an embodiment of the disclosure, the circuit boards 140 may be connected to a timing controller and/or a power supply unit through another circuit board or a connector.

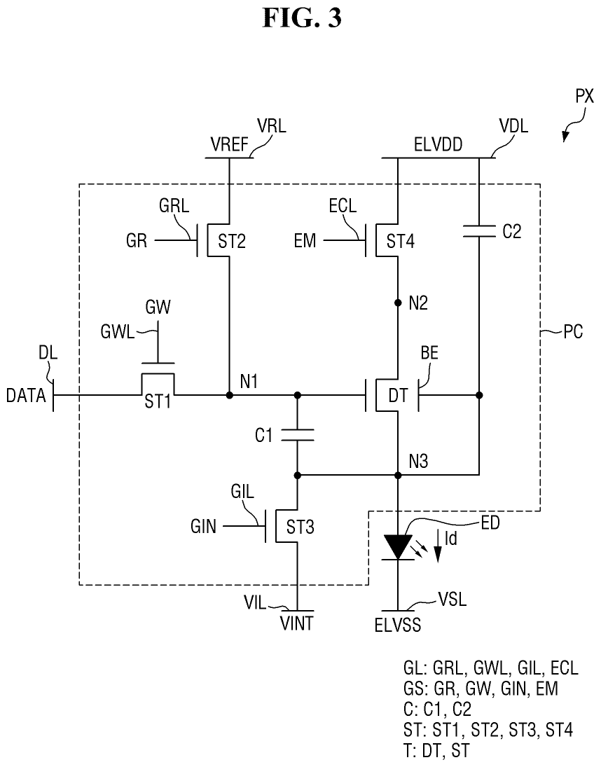

FIG. 3 is a schematic diagram of an equivalent circuit of a pixel PX according to an embodiment of the disclosure. For example, FIG. 3 schematically shows a pixel PX of a light-emitting display device including a light-emitting element ED. The type and/or structure of the pixel PX that may be included in the display device 100 may vary depending on embodiments.

Referring to FIG. 3, the pixel PX may include a light-emitting element ED and a pixel circuit PC connected to the light-emitting element ED. The light-emitting element ED may be a light source of the pixel PX and may be, but is not limited to, an organic light-emitting diode. The pixel circuit PC may control the emission timing and brightness of the light-emitting element ED.

The pixel circuit PC may supply the driving current Id to the light-emitting element ED in response to the driving signals supplied from the first driver 120 and the second driver 130. For example, the pixel circuit PC may supply the driving current Id to the light-emitting element ED in response to the gate signals GS supplied from the first driver 120 through the respective gate lines GL and the data signal DATA supplied from the second driver 130 through the data lines DL.

The pixel PX may be connected to a first gate line GWL transmitting a first gate signal GW (e.g., a scan signal), a second gate line GIL transmitting a second gate signal GIN, a third gate line GRL transmitting a third gate signal GR, an emission control line ECL transmitting an emission control signal EM, and a data line DL transmitting a data signal DATA. The pixel PX may be connected to a first voltage line VDL transmitting a first pixel voltage ELVDD (also referred to as “first pixel supply voltage” or “driving voltage”), and a second voltage line VSL transmitting a second pixel voltage ELVSS (also referred to as “second pixel supply voltage” or “common voltage”). According to an embodiment of the disclosure, the pixel PX may be further connected to an initialization voltage line VIL transmitting an initialization voltage VINT (also referred to as “third pixel supply voltage”), and a reference voltage line VRL transmitting a reference voltage VREF (also referred to as “fourth pixel supply voltage”).

The pixel circuit PC may include transistors T and at least one capacitor C. For example, the pixel circuit PC may include a driving transistor DT, one or more switching transistors ST, and a first capacitor C1 and a second capacitor C2. According to an embodiment of the disclosure, the pixel circuit PC may include four switching transistors ST, e.g., a first switching transistor ST1, a second switching transistor ST2, a third switching transistor ST3 and a fourth switching transistor ST4.

The driving transistor DT may control the magnitude of the driving current Id supplied to the light-emitting element ED according to the gate-source voltage. The switching transistors ST may be turned on or turned off depending on respective gate-source voltages. Depending on the type (e.g., p-type or n-type transistor) and/or operating conditions of each of the transistors T, the first electrode of each of the transistors T may be a drain electrode (or drain region) or a source electrode (or source region) while the second electrode thereof may be an electrode different from the first electrode. For example, in case that the first electrode is a drain electrode, the second electrode may be a source electrode.

Although FIG. 3 illustrates that all of the transistors T are n-type transistors, the types of the transistors T are not limited thereto. In another embodiment, at least one transistor T may be formed as a p-type transistor.

According to an embodiment of the disclosure, the transistors may be located in the respective pixel areas and may be oxide transistors (also referred to as “oxide semiconductor transistors”) including an oxide semiconductor. For example, the active layer of each of the transistors DT and ST1 to ST4 may include an oxide semiconductor. It should be understood, however, that the disclosure is not limited thereto. For example, at least one transistor T may be formed of a semiconductor material other than an oxide semiconductor (e.g., amorphous silicon or polysilicon).

According to an embodiment of the disclosure, the transistors T provided in each pixel PX as well as the transistors T disposed on the display panel 110 may all be oxide transistors including an oxide semiconductor. Oxide semiconductors have high carrier mobility and low leakage current, and accordingly, a large voltage drop may not occur even in case that an oxide transistor is driven for a long period of time. For example, the pixel PX including an oxide transistor may be driven at a low frequency because changes in brightness and/or color of images due to a voltage drop may be ignorable even when driven at a low frequency. In case that the transistors T are formed of oxide transistors, it may be possible to suppress or prevent leakage current of the pixel PX and to save power consumption.

Oxide semiconductor may be sensitive to light, and thus the amount of electric current may change due to external light. According to an embodiment of the disclosure, a light-blocking pattern or a light-blocking electrode (e.g., a bottom electrode BE or a back-gate electrode) may be disposed under the active layer included in at least one transistor T to block external light. Accordingly, the operating characteristics of the transistor T may be stabilized.

The driving transistor DT may include a gate electrode connected to a first node N1, a first electrode (e.g., a drain electrode) connected to a second node N2, and a second electrode (e.g., a source electrode) connected to a third node N3. The first electrode of the driving transistor DT may be connected to the first voltage line VDL via the fourth transistor ST4, and the second electrode may be connected to the light-emitting element ED. The driving transistor DT may control the magnitude (e.g., amount of current) of the driving current Id flowing to the light-emitting element ED in response to the data signal DATA transmitted to the first node N1.

According to an embodiment of the disclosure, the driving transistor DT may further include a bottom electrode BE (or a light-blocking layer) connected to the third node N3. The bottom electrode BE of the driving transistor DT may be connected to the third node N3 so that the driving transistor DT is implemented as a transistor with a double-gate structure (e.g., a double-gate transistor with a source-sync structure), thereby improving the operating characteristics of the driving transistor DT. The bottom electrode BE of the driving transistor DT may be disposed under the active layer of the driving transistor DT to block external light.

The first switching transistor ST1 may include a gate electrode connected to the first gate line GWL, a first electrode connected to the data line DL, and a second electrode connected to the first node N1. The first switching transistor ST1 may be turned on by the first gate signal GW (e.g., the first gate signal GW of a gate-on voltage) transmitted to the first gate line GWL to connect the data line DL with the first node N1. Accordingly, the data signal DATA transmitted on the data line DL may be transmitted to the first node N1.

The second switching transistor ST2 may include a gate electrode connected to the third gate line GRL, a first electrode connected to the reference voltage line VRL, and a second electrode connected to the first node N1. The second switching transistor ST2 may be turned on by the third gate signal GR transmitted to the third gate line GRL and may transmit the reference voltage VREF transmitted to the reference voltage line VRL to the first node N1.

The third switching transistor ST3 may include a gate electrode connected to the second gate line GIL, a first electrode connected to the third node N3, and a second electrode connected to the initialization voltage line VIL. The third switching transistor ST3 may be turned on by the second gate signal GIN transmitted on the second gate line GIL, and may transmit the initialization voltage VINT transmitted on the initialization voltage line VIL to the third node N3.

The fourth transistor ST4 may include a gate electrode connected to the emission control line ECL, a first electrode connected to the first voltage line VDL, and a second electrode connected to the second node (or the first electrode of the driving transistor DT). The fourth transistor ST4 may be turned on by the emission control signal EM (e.g., the emission control signal EM of the gate-on voltage) transmitted on the emission control line ECL to control the timing of emission of the pixel PX.

Each of the switching transistors ST may or may not include a bottom electrode (or light-blocking layer) under the active layer. According to an embodiment of the disclosure, at least one of the switching transistors ST may include a bottom electrode, and the bottom electrode of the at least one switching transistor ST may be connected to the gate electrode of that switching transistor ST. By connecting the bottom electrode of a switching transistor ST to the gate electrode, the off characteristics and switching speed of the switching transistor ST may be improved, an additional voltage tolerance range may be obtained, leakage current may be reduced, and voltage stability may be improved. According to another embodiment, no bottom electrode may be disposed under the active layer of the switching transistors ST.

A first capacitor C1 may be connected between the first node N1 and the third node N3. The first capacitor C1 may be a storage capacitor of the pixel PX and may store a voltage corresponding to a data signal DATA (e.g., data voltage).

A second capacitor C2 may be connected between the first voltage line VDL and the third node N3. According to an embodiment of the disclosure, the capacitance of the second capacitor C2 may be smaller than the capacitance of the first capacitor C1.

The light-emitting element ED may be connected between the third node N3 and the second voltage line VSL. For example, the light-emitting element ED may include a first electrode (e.g., anode electrode) connected to the third node N3, a second electrode (e.g., cathode electrode) facing the first electrode and connected to the second voltage line VSL, and an emissive layer interposed between the first electrode and the second electrode. According to an embodiment of the disclosure, the first electrode of the light-emitting element ED may be an individual electrode disposed separately in each of the pixels PX, while the second electrode of the light-emitting element ED may be a common electrode shared by multiple pixels PX. The light-emitting element ED may emit light with a brightness in proportional to the driving current Id supplied from the pixel circuit PC.

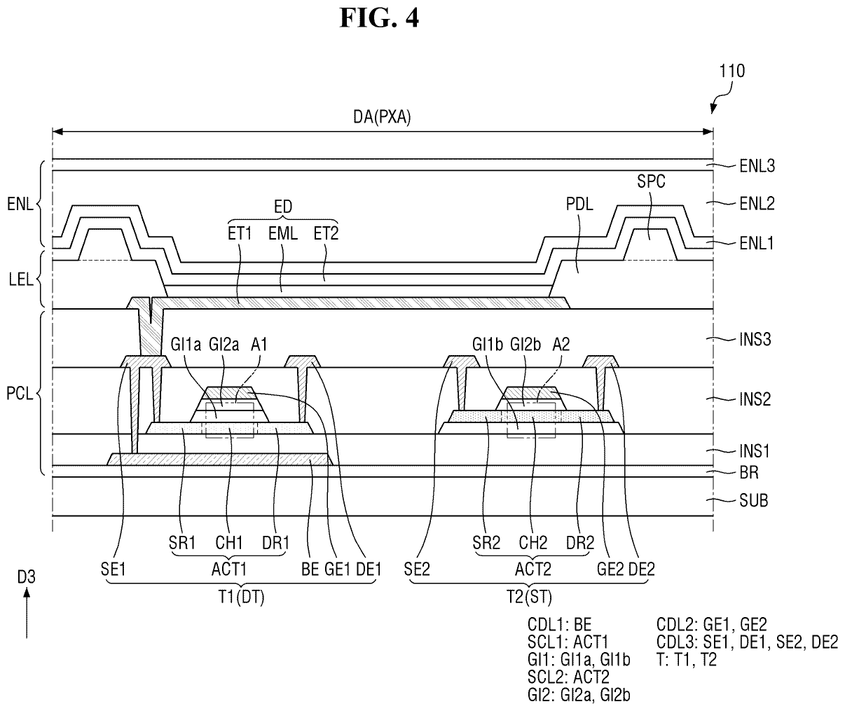

FIG. 4 is a schematic cross-sectional view showing the display panel 110 according to an embodiment of the disclosure. For example, FIG. 4 schematically shows a portion of the display area DA of the display panel 110. FIG. 4 schematically shows a light-emitting display panel including a light-emitting element ED (e.g., an organic light-emitting diode) as an embodiment of the display panel 110.

Referring to FIG. 4, the display panel 110 may include a substrate SUB (or a “base layer”), a panel circuit layer PCL, a light-emitting element layer LEL, and an encapsulation layer ENL. The panel circuit layer PCL, the light-emitting element layer LEL and the encapsulation layer ENL may be disposed on the substrate SUB and may overlap one another. For example, in the display area DA, the panel circuit layer PCL, the light-emitting element layer LEL and the encapsulation layer ENL may be sequentially disposed on the substrate SUB in the third direction D3. The positions of the panel circuit layer PCL, the light-emitting element layer LEL and/or the encapsulation layer ENL may be changed.

According to an embodiment of the disclosure, the display panel 110 may further include additional elements provided on and/or under the encapsulation layer ENL. For example, the display panel 110 may further include at least one of a sensor layer (e.g., a touch sensor layer), an optical layer (e.g., a color filter layer and/or a wavelength conversion layer), and a protective layer (e.g., a protective film, an insulating layer, an upper substrate and/or a window). Each of the sensor layer, optical layer and/or protective layer may be provided over the encapsulation layer ENL or between the light-emitting element layer LEL and the encapsulation layer ENL.

The substrate SUB may be a base member for forming the display panel 110 and may be a rigid or flexible substrate (or film). According to an embodiment of the disclosure, the substrate SUB may be a substrate that includes an insulating material such as glass and is rigid, which may not be bendable. In another embodiment, the substrate SUB may be a flexible substrate that includes polyimide or other insulating material and allows deformation such as bending, folding or rolling, and may be bent or not bent. The type and/or material of the substrate SUB may be altered depending on the embodiments.

The panel circuit layer PCL (e.g., a pixel circuit layer or a thin-film transistor layer) may be disposed on the substrate SUB. The panel circuit layer PCL may include circuit elements including transistors T and capacitors C of the pixels PX, and lines (e.g., signal lines and voltage lines). According to an embodiment of the disclosure, the panel circuit layer PCL may further include circuit elements of the first driver 120 (e.g., driver transistors and/or driver capacitors provided in the first driver 120), and/or additional conductive patterns (e.g., bridge patterns).

FIG. 4 shows a first transistor T1 and a second transistor T2 disposed in one pixel area PXA as an embodiment of circuit elements that may be provided in the panel circuit layer PCL. The first transistor T1 in FIG. 4 may be the driving transistor DT of the pixel PX. For example, the first transistor T1 of FIG. 4 may be the driving transistor DT of FIG. 3. The second transistor T2 of FIG. 4 may be a switching transistor ST of the pixel PX. For example, the second transistor T2 of FIG. 4 may be one of the first to fourth switching transistors ST1 to ST4 of FIG. 3.

According to an embodiment of the disclosure, the switching transistors ST provided in the pixels PX may be formed simultaneously using a same oxide semiconductor and may have substantially a same cross-sectional structure. According to an embodiment of the disclosure, the driving transistor DT and the switching transistors ST provided to each pixel PX may be formed using different oxide semiconductors. For example, the active layer (e.g., first active layer ACT1) of the driving transistor DT and the active layers (e.g., second active layers ACT2) of the switching transistors ST may use different oxide semiconductors.

According to an embodiment of the disclosure, the panel circuit layer PCL may include a barrier layer BR. For example, the barrier layer BR may be disposed on the substrate SUB, and circuit elements and lines may be disposed on the barrier layer BR.

The panel circuit layer PCL may include multiple conductive layers and at least one semiconductor layer SCL disposed on the barrier layer BR. In the conductive layers, electrodes forming circuit elements (e.g., transistors T and capacitors C) of the panel circuit layer PCL, conductive patterns (e.g., bridge electrodes) and/or lines connected to the circuit elements may be disposed. The active layers ACT of the transistors TR formed in the panel circuit layer PCL may be disposed in the at least one semiconductor layer SCL.

According to an embodiment, the panel circuit layer PCL may include multiple semiconductor layers. For example, the panel circuit layer PCL may include a first semiconductor layer SCL1 including the first active layer ACT1 of the first transistor T1 (e.g., the driving transistor DT) of each pixel PX, and a second semiconductor layer SCL2 including the second active layer ACT2 of the second transistor T2 (e.g., at least one switching transistor ST) of each pixel PX.

According to an embodiment of the disclosure, the panel circuit layer PCL may include: a first conductive layer CDL1 (e.g., a bottom conductive layer), a first semiconductor layer SCL1 (e.g., a first oxide semiconductor layer), a second semiconductor layer SCL2 (e.g., a second oxide semiconductor layer), a second conductive layer CDL2 (e.g., a gate conductive layer) and a third conductive layer CDL3 (e.g., a source-drain conductive layer or a data conductive layer), which are sequentially disposed on the barrier layer BR (or substrate SUB) in the third direction D3. The insulating layers and/or insulating patterns may be disposed between the conductive layers and semiconductor layers of the panel circuit layer PCL.

According to an embodiment of the disclosure, the panel circuit layer PCL may further include at least one conductive layer disposed on the third conductive layer CDL3 and at least one insulating layer covering the at least one conductive layer. The at least one conductive layer may include a bridge electrode connecting the light-emitting element ED with the pixel circuit PC of each pixel PX, and/or at least one line, etc.

Patterns included in each conductive layer of the panel circuit layer PCL (e.g., electrodes, conductive patterns and/or lines of each conductive layer) may include at least one conductive material. For example, the patterns provided or included in each of the first conductive layer CDL1, the second conductive layer CDL2, and the third conductive layer CDL3 may include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg), the like, an alloy thereof, and a conductive material. According to an embodiment of the disclosure, the patterns included in the same conductive layer may be formed simultaneously using a same conductive material.

According to an embodiment of the disclosure, the patterns provided in each of the conductive layers of the panel circuit layer PCL may have a single-layer or multi-layer structure. For example, the patterns provided or included in the first conductive layer CDL1, the second conductive layer CDL2 and the third conductive layer CDL3, respectively, may have a single-layer or multi-layer structure. According to an embodiment of the disclosure, the patterns included in the same conductive layer may have a same cross-sectional structure.

The panel circuit layer PCL may further include insulating layers and/or insulating patterns disposed on the substrate SUB. For example, the panel circuit layer PCL may include a barrier layer BR, a first insulating layer INS1 (e.g., buffer layer), a first gate insulating layer GI1, a second gate insulating layer GI2, a second insulating layer INS2 (e.g., interlayer dielectric layer), and a third insulating layer INS3 (e.g., a planarization layer) sequentially disposed on the substrate SUB in the third direction D3.

According to an embodiment of the disclosure, at least one insulating layer provided in the panel circuit layer PCL may be disposed entirely in the display area DA. For example, the barrier layer BR, the first insulating layer INS1, the second insulating layer INS2, and the third insulating layer INS3 may be disposed entirely in the display area DA.

Each of the first gate insulating layer GI1 and the second gate insulating layer GI2 may be partially disposed only in the respective pixel areas PXA and a portion of the display area DA including pixel areas PXA, or may be disposed entirely in the display area DA. According to the embodiment of FIG. 4, the first gate insulating layer GI1 and the second gate insulating layer GI2 may be partially disposed only in the respective pixel areas PXA and a portion of the display area DA including pixel areas PXA.

The barrier layer BR may be disposed between the substrate SUB and the first conductive layer CDL1. The barrier layer BR may include at least one inorganic layer including an inorganic insulating material (e.g., silicon nitride, silicon oxide, silicon oxynitride, titanium oxide, aluminum oxide, or other inorganic insulating materials). The barrier layer BR may protect the pixels PX from moisture permeating through the substrate SUB, which may be vulnerable to moisture permeation. The material of the barrier layer BR may vary depending on embodiments.

The first insulating layer INS1 may be disposed on the first conductive layer CDL1. For example, the first insulating layer INS1 may be disposed on the barrier layer BR (or the substrate SUB) and may cover the patterns of the first conductive layer CDL1. The first insulating layer INS1 may include at least one inorganic layer including an inorganic insulating material (e.g., silicon nitride, silicon oxide, silicon oxynitride, titanium oxide, aluminum oxide, or other inorganic insulating materials).

The first gate insulating layer GI1 may be disposed on the first insulating layer INS1 and the first semiconductor layer SCL1. The first gate insulating layer GI1 may include at least one inorganic insulating layer including an inorganic insulating material. According to an embodiment of the disclosure, the first gate insulating layer GI1 may include multiple oxide layers (e.g., silicon oxide layers), and at least one nitride layer (e.g., silicon nitride layer) disposed between the oxide layers.

According to an embodiment of the disclosure, the first gate insulating layer GI1 may be disposed on a part of each of first insulating layer INS1 and the first semiconductor layer SCL1. For example, the first gate insulating layer GI1 may include a first portion GI1a disposed on the first active layer ACT1 of the first semiconductor layer SCL1, and a second portion GI1b disposed on a part of the first insulating layer INS1. The first portion GI1a and the second portion GI1b of the first gate insulating layer GI1 may be an integrated insulating layer (or insulating pattern) that is connected with each other, or may be individual insulating layers (or insulating patterns) that are separated from each other in a plan view.

According to an embodiment of the disclosure, the first portion GI1a of the first gate insulating layer GI1 may be partially disposed only on a portion of the first active layer ACT1. For example, the first portion GI1a of the first gate insulating layer GI1 may be disposed only on a portion of the first active layer ACT1 including a first channel region CH1 (a channel region of the first active layer ACT1), and may expose other portions of the first active layer ACT1 including at least a portion of each of a first source region SR1 (a source region of the first active layer ACT1) and a first drain region DR1 (a drain region of the first active layer ACT1).

As the first gate insulating layer GI1 exposes the first source region SR1 and the first drain region DR1, the first source region SR1 and the first drain region DR1 may become conductive properly and/or readily during the process of fabricating the display panel 110. For example, during etching the first gate insulating layer GI1 such that at least a portion of each of the first source region SR1 and the first drain region DR1 is exposed, there may be oxygen vacancy in the first source region SR1 and the first drain region DR1. Accordingly, the first source region SR1 and the first drain region DR1 may become conductive properly in a subsequent process (e.g., a process of forming the second insulating layer INS2, etc.) without performing a separate doping process.

The second portion GI1b of the first gate insulating layer GI1 may be partially disposed only on a portion of the first insulating layer INS1. For example, the second portion GI1b of the first gate insulating layer GI1 may be disposed on a portion of the first insulating layer INS1 that overlaps the second active layer ACT2 in a plan view (e.g., in the third direction D3). For example, the second portion GI1b of the first gate insulating layer GI1 may be disposed between the first insulating layer INS1 and the second active layer ACT2.

The second gate insulating layer GI2 may be disposed on the first gate insulating layer GI1 and the second semiconductor layer SCL2. The second gate insulating layer GI2 may include at least one inorganic insulating layer including an inorganic insulating material. For example, the second gate insulating layer GI2 may include at least one oxide layer including silicon oxide (SiOₓ) or another oxide.

According to an embodiment of the disclosure, the second gate insulating layer GI2 may be disposed on a portion of each of the first gate insulating layer GI1 and the second semiconductor layer SCL2. For example, the second gate insulating layer GI2 may include a first portion GI2a disposed on the first portion GI1a of the first gate insulating layer GI1 on the first active layer ACT1, and a second portion GI2b disposed on the second active layer ACT2 of the second semiconductor layer SCL2 on the insulating layer INS1. The first portion GI2a and the second portion GI2b of the second gate insulating layer GI2 may be an integrated insulating layer (or insulating pattern) that is connected with each other, or may be individual insulating layers (or insulating patterns) that are separated from each other in a plan view.

According to an embodiment of the disclosure, the first portion GI2a of the second gate insulating layer GI2 may be partially disposed only on a portion of the first active layer ACT1. For example, the first portion GI2a of the second gate insulating layer GI2 may be disposed only on a portion of the first active layer ACT1 including the first channel region CH1, and may expose other portions of the first active layer ACT1 including at least a portion of each of the first source region SR1 and the first drain region DR1.

The second portion GI2b of the second gate insulating layer GI2 may be partially disposed only on a portion of the second active layer ACT2. For example, the second portion GI2b of the second gate insulating layer GI2 may be disposed only on a portion of the second active layer ACT2 including a second channel region CH2 (a channel region of the second active layer ACT2), and may expose other portions of the second active layer ACT2 including at least a portion of each of a second source region SR2 (a source region of the second active layer ACT2) and a second drain region DR2 (a drain region of the second active layer ACT2).

As the second gate insulating layer GI2 exposes the first source region SR1, the first drain region DR1, the second source region SR2 and the second drain region DR2, the first source region SR1, the first drain region DR1, the second source region SR2 and the second drain region DR2 may become conductive properly and/or readily during the process of fabricating the display panel 110. For example, during etching the second gate insulating layer GI2 or the like, there may be oxygen vacancy in the first source region SR1, the first drain region DR1, the second source region SR2 and/or the second drain region DR2. Accordingly, the first source region SR1, the first drain region DR1, the second source region SR2 and the second drain region DR2 may be properly conductive in subsequent processes without performing a separate doping process.

The second insulating layer INS2 may be disposed over the first insulating layer INS1, the first semiconductor layer SCL1, the first gate insulating layer GI1, the second semiconductor layer SCL2, the second gate insulating layer GI2, and the second conductive layer CDL2. For example, the second insulating layer INS2 may be disposed on the second insulating layer INS2 and cover the first semiconductor layer SCL1, the first gate insulating layer GI1, the second semiconductor layer SCL2, the second gate insulating layer GI2, and the second conductive layer CDL2. The second insulating layer INS2 may include at least one inorganic insulating layer including an inorganic insulating material.

The third insulating layer INS3 may be disposed over the third conductive layer CDL3. For example, the third insulating layer INS3 may be disposed on the second insulating layer INS2 and cover the patterns of the third conductive layer CDL3. The third insulating layer INS3 may include at least one organic insulating layer including an organic insulating material (e.g., an acrylic resin, an epoxy resin, a phenolic resin, a polyamide resin, a polyimide resin, or other organic insulating materials). The third insulating layer INS3 may or may not include an inorganic insulating layer. A surface (e.g., upper surface) of the third insulating layer INS3 may be substantially flat.

The first transistor T1 may include a first active layer ACT1 and a first gate electrode GE1 overlapping the first active layer ACT1 in a plan view. According to an embodiment of the disclosure, the first gate electrode GE1 may be disposed on a portion of the first active layer ACT1. For example, the first gate electrode GE1 may be a top-gate electrode.

According to an embodiment of the disclosure, the first transistor T1 may further include at least one of a first source electrode SE1 and a first drain electrode DE1. For example, the first transistor T1 may further include a first source electrode SE1 connected to the first source region SR1, and a first drain electrode DE1 connected to the first drain region DR1. In another embodiment, the first transistor T1 may not include separate source electrode and/or drain electrode, and the first source region SR1 and/or the first drain region DR1 may be connected to other circuit elements, lines and/or conductive patterns to function as a source electrode and/or drain electrode of the first transistor T1.

According to an embodiment of the disclosure, the first transistor T1 may further include a bottom electrode BE (or a light-blocking layer) disposed under the first active layer ACT1. According to an embodiment of the disclosure, the bottom electrode BE may be connected to an electrode (e.g., the first source electrode SE1) of the first transistor T1, and may be used as a back-gate electrode (or bottom-gate electrode) to adjust the characteristics of the first transistor T1. For example, the bottom electrode BE may be electrically connected to the first source electrode SE1 through at least one contact hole penetrating the first insulating layer INS1 and the second insulating layer INS2. By disposing the bottom electrode BE under the first active layer ACT1, it may be possible to block external light from entering the first channel region CH1.

According to an embodiment of the disclosure, the first transistor T1 may be an oxide transistor. For example, the first transistor T1 may be an n-type oxide transistor.

The bottom electrode BE may be provided to or included in the first conductive layer CDL1 disposed on the barrier layer BR (or the substrate SUB). For example, the bottom electrode BE may be disposed between the barrier layer BR (or the substrate SUB) and the first insulating layer INS1.

The bottom electrode BE may overlap the first active layer ACT1 and the first gate electrode GE1 in a plan view. For example, the bottom electrode BE may be disposed below the first active layer ACT1 and overlap at least a portion of the first active layer ACT1 including the first channel region CH1, and may face the first gate electrode GE1 with the first active layer ACT1 interposed between the first gate electrode GE1 and the bottom electrode BE.

The first active layer ACT1 may be provided to or included in the first semiconductor layer SCL1. For example, the first active layer ACT1 may be disposed on the first insulating layer INS1 and may be covered with the first gate insulating layer GI1 and the second insulating layer INS2.

The first active layer ACT1 may include the first channel region CH1, and the first source region SR1 and the first drain region DR1 spaced apart from each other with the first channel region CH1 interposed between the first source region SR1 and the first drain region DR1. For example, the first source region SR1 and the first drain region DR1 may be located on sides of the first channel region CH1, respectively. The first source region SR1 and the first drain region DR1 may have a higher carrier concentration (e.g., electron concentration) than the first channel region CH1.

The first active layer ACT1 may overlap the bottom electrode BE and the first gate electrode GE1 in a plan view. For example, a part of the first active layer ACT1 including the channel region CH may overlap the bottom electrode BE and the first gate electrode GE1 in the third direction D3.

According to an embodiment of the disclosure, the first active layer ACT1 may include oxide semiconductor. For example, the first active layer ACT1 may include an oxide semiconductor including at least one of indium (In), gallium (Ga), zinc (Zn), tin (Sn), and hafnium (Hf), or another oxide semiconductor. According to an embodiment of the disclosure, the first active layer ACT1 may include at least one of zinc oxide (ZnO), zinc-tin oxide (ZTO), indium-zinc oxide (IZO), indium oxide (InO or In₂O₃), titanium oxide (TiO or TiO₂), indium-gallium oxide (IGO), indium-gallium-zinc oxide (IGZO), indium-gallium-tin oxide (IGTO), indium-zinc-tin oxide (IZTO), indium-tin-gallium-zinc oxide (ITGZO), and the like.

According to an embodiment of the disclosure, the first active layer ACT1 may have a first mobility (e.g., a first electron mobility) suitable for using the first transistor T1 as the driving transistor DT of the pixel PX. For example, the first active layer ACT1 may include a first oxide semiconductor having a first mobility that ensures an appropriate driving voltage range without significantly causing deviation or change in the characteristics such as the threshold voltage. For example, the first active layer ACT1 may be formed of a first oxide semiconductor that has a relatively low mobility compared to the second active layer ACT2 of the second transistor T2 used as the switching transistor ST of the pixel PX. According to an embodiment of the disclosure, the first oxide semiconductor may include, but is not limited to, indium-gallium-zinc oxide (IGZO).

The first gate insulating layer GI1 and the second gate insulating layer GI2 may be disposed on the first active layer ACT1. For example, the first gate insulating layer GI1 and the second gate insulating layer GI2 may be sequentially disposed on a portion of the first active layer ACT1 including the first channel region CH1.

The first gate electrode GE1 may be disposed on the first gate insulating layer GI1 and the second gate insulating layer GI2. For example, the first gate electrode GE1 may be disposed on the second gate insulating layer GI2 in a first transistor area where the first transistor T1 is disposed. The first gate electrode GE1 may be provided to or included in the second conductive layer CDL2. The second conductive layer CDL2 may be disposed on the second gate insulating layer GI2 and may be covered with the second insulating layer INS2.

The first gate electrode GE1 may be disposed on the first active layer ACT1. For example, the first gate electrode GE1 may be disposed on the first portions GI1a and GI2a of the first gate insulating layer GI1 and the second gate insulating layer GI2 covering the first channel region CH1. The first gate electrode GE1 and the first active layer ACT1 may be separated from each other with the first gate insulating layer GI1 and the second gate insulating layer GI2 interposed between the first gate electrode GE1 and the first active layer ACT1.

The first source electrode SE1 and the first drain electrode DE1 may be provided to or included in the third conductive layer CDL3. The third conductive layer CDL3 may be disposed on the second insulating layer INS2 covering the second conductive layer CDL2, etc., and may be covered with the third insulating layer INS3.

The first source electrode SE1 may be connected to a portion of the first active layer ACT1. For example, the first source electrode SE1 may be electrically connected to the first source region SR1 through at least one contact hole penetrating the second insulating layer INS2. According to an embodiment of the disclosure, the first source electrode SE1 may be electrically connected also to the bottom electrode BE through at least one contact hole penetrating the first insulating layer INS1 and the second insulating layer INS2.

The first drain electrode DE1 may be connected to another portion of the first active layer ACT1. For example, the first drain electrode DE1 may be electrically connected to the first drain region DR1 through at least one contact hole penetrating the second insulating layer INS2.

The first transistor T1 of each pixel PX may be electrically connected to the light-emitting element ED of each pixel PX. For example, the first transistor T1 disposed in each pixel area PXA may be electrically connected to the first electrode ET1 of the light-emitting element ED disposed in each pixel area PXA in the light-emitting element layer LEL.

The second transistor T2 may include a second active layer ACT2 and a second gate electrode GE2 overlapping the second active layer ACT2 in a plan view. According to an embodiment of the disclosure, the second gate electrode GE2 may be disposed on a portion of the second active layer ACT2. For example, the second gate electrode GE2 may be a top-gate electrode.

According to an embodiment of the disclosure, the second transistor T2 may further include at least one of a second source electrode SE2 and a second drain electrode DE2. For example, the second transistor T2 may further include the second source electrode SE2 connected to the second source region SR2 of the second active layer ACT2, and the second drain electrode DE2 connected to the second drain region DR2 of the second active layer ACT2. In another embodiment, the second transistor T2 may not include separate source electrode and/or drain electrode, and the second source region SR2 and/or the second drain region DR2 may be connected to other circuit elements, lines and/or conductive patterns to function as a source electrode and/or drain electrode of the second transistor T2. The second transistor T2 may or may not include a bottom electrode disposed under the second active layer ACT2.

According to an embodiment of the disclosure, the second transistor T2 may be an oxide transistor. For example, the second transistor T12 may be an n-type oxide transistor.

The second active layer ACT2 may be provided to or included in the second semiconductor layer SCL2. For example, the second active layer ACT2 may be disposed on the first gate insulating layer GI1 and may be covered with the second gate insulating layer GI2 and the second insulating layer INS2.

The second active layer ACT2 may be disposed between the first gate insulating layer GI1 and the second gate insulating layer GI2 at a position spaced apart from the first active layer ACT1. For example, the first active layer ACT1 and the second active layer ACT2 may be separated and/or spaced apart from each other in a plan view defined by the first direction D1 and the second direction D2, and may not overlap each other in the third direction D3.

The second active layer ACT2 may include the second channel region CH2, and the second source region SR2 and the second drain region DR2 spaced apart from each other with the second channel region CH2 interposed between the second source region SR2 and the second drain region DR2. For example, the second source region SR2 and the second drain region DR2 may be located on sides of the second channel region CH2, respectively. The second source region SR2 and the second drain region DR2 may have a higher carrier concentration (e.g., electron concentration) than the second channel region CH2.

The second active layer ACT2 may overlap the second gate electrode GE2 in a plan view. For example, a portion of the second active layer ACT2 including the second channel region CH2 may overlap the second gate electrode GE2 in the third direction D3.

According to an embodiment of the disclosure, the second active layer ACT2 may include oxide semiconductor. For example, the second active layer ACT2 may include an oxide semiconductor including at least one of indium (In), gallium (Ga), zinc (Zn), tin (Sn) and hafnium (Hf), and the like. According to an embodiment of the disclosure, the second active layer ACT2 may include at least one of zinc oxide (ZnO), zinc-tin oxide (ZTO), indium-zinc oxide (IZO), indium oxide (InO or In2O3), titanium oxide (TiO or TiO2), indium-gallium oxide (IGO), indium-gallium-zinc oxide (IGZO), indium-gallium-tin oxide (IGTO), indium-zinc-tin oxide (IZTO), indium-tin-gallium-zinc oxide (ITGZO), and the like.

According to an embodiment of the disclosure, the second active layer ACT2 may have a second mobility (e.g., a second electron mobility) suitable for using the second transistor T2 as a switching transistor ST of the pixel PX. For example, the second active layer ACT2 may include a second oxide semiconductor having a second mobility higher than the first mobility of the first active layer ACT1 to enable fast switching operation.

According to an embodiment of the disclosure, the second active layer ACT2 may include a second oxide semiconductor that is different from the first oxide semiconductor of the first active layer ACT1. For example, the second active layer ACT2 may be formed of a second oxide semiconductor that has a relatively high mobility compared to the first active layer ACT1 of the first transistor T1 used as a driving transistor DT of the pixel PX. According to an embodiment of the disclosure, the second oxide semiconductor may include, but is not limited to, indium-tin-gallium-zinc oxide (ITGZO) (e.g., high-mobility indium-tin-gallium-zinc oxide (ITGZO), which has a higher mobility than indium-gallium-zinc oxide (IGZO)) or indium-gallium oxide (IGO) (e.g., crystallized, high-mobility indium-gallium oxide (IGO)). For example, the second oxide semiconductor may include a high-mobility oxide semiconductor (e.g., an oxide semiconductor with a higher mobility than the first oxide semiconductor forming the first active layer ACT1) other than indium-tin-gallium-zinc oxide (ITGZO) and indium-gallium oxide (IGO).

The second gate insulating layer GI2 may be disposed on the second active layer ACT2. For example, the second gate insulating layer GI2 may be disposed on a portion of the second active layer ACT2 including the second channel region CH2.

The second gate electrode GE2 may be disposed on the second gate insulating layer GI2. For example, the second gate electrode GE2 may be disposed on the second gate insulating layer GI2 in a second transistor area where the second transistor T2 is disposed. According to an embodiment of the disclosure, the first gate electrode GE1 and the second gate electrode GE2 may be disposed in the same conductive layer and may be formed simultaneously. For example, the second gate electrode GE2 may be provided to or included in the second conductive layer CDL2.

The second gate electrode GE2 may be disposed on the second active layer ACT2. For example, the second gate electrode GE2 may be disposed on the second portion GI2b of the second gate insulating layer GI2 covering the second channel region CH2. The second gate electrode GE2 and the second active layer ACT2 may be separated from each other with the second gate insulating layer GI2 interposed between the second gate electrode GE2 and the second active layer ACT2.

The second source electrode SE2 and the second drain electrode DE2 may be disposed on the second insulating layer INS2. According to an embodiment of the disclosure, the first source electrode SE1, the first drain electrode DE1, the second source electrode SE2 and/or the second drain electrode DE2 may be provided in the same conductive layer and may be formed simultaneously. For example, the first source electrode SE1, the first drain electrode DE1, the second source electrode SE2 and/or the second drain electrode DE2 may be provided or included in the third conductive layer CDL3.

The second source electrode SE2 may be connected to a portion of the second active layer ACT2. For example, the second source electrode SE2 may be electrically connected to the second source region SR2 through at least one contact hole penetrating the second insulating layer INS2.

The second drain electrode DE2 may be connected to another portion of the second active layer ACT2. For example, the second drain electrode DE2 may be electrically connected to the second drain region DR2 through at least one contact hole penetrating the second insulating layer INS2.

The third conductive layer CDL3 including the first source electrode SE1, the first drain electrode DE1, the second source electrode SE2 and/or the second drain electrode DE2 may be covered with the third insulating layer INS3.

The light-emitting element layer LEL may be disposed on the panel circuit layer PCL. For example, the light-emitting element layer LEL may be disposed on the third insulating layer INS3 and may be located at least in the display area DA.

The light-emitting element layer LEL may include a light-emitting element ED of each of the pixels PX. For example, the light-emitting element layer LEL may include a pixel-defining layer PDL (also referred to as a “bank”) that partitions the emission area of each of the pixels PX, and a light-emitting element ED located in each emission area. According to an embodiment of the disclosure, the light-emitting element layer LEL may further include a spacer SPC disposed on a portion of the pixel-defining layer PDL.

Each of the light-emitting elements EL may include a first electrode ET1 located in each emission area, and an emissive layer EML and a second electrode ET2 sequentially disposed on the first electrode ET1. The first electrode ET1 of the light-emitting element ED may be connected to at least one transistor (e.g., the first transistor T1) included in that pixel PX.

The first electrode ET1 of the light-emitting element ED may be a single-layer or multi-layer electrode including at least one conductive material. According to an embodiment of the disclosure, the display panel 110 may be a top-emission display panel, and the first electrode ET1 may include a reflective electrode layer with high reflectivity.

The emissive layer EML of each of the light-emitting elements ED may include a high-molecular substance or a low-molecular substance. Light emitted from the emissive layer EML may contribute to displaying images.

Although FIG. 4 shows the display panel 110 in which the emissive layer EML of the light-emitting element ED is individually formed in the respective pixel area PXA, the disclosure is not limited thereto. For example, the display panel 110 may include light-emitting elements in a tandem structure including the emissive layer EML formed as a common film over the entire display area DA.

The second electrode ET2 of the light-emitting element ED may include a conductive material. According to an embodiment of the disclosure, the second electrode ET2 may be a common layer formed over the entire display area DA and cover the emissive layer EML and the pixel-defining layer PDL. According to an embodiment of the disclosure, the display panel 110 may be a top-emission display panel, and the second electrode ET2 may include a transparent or translucent electrode layer.

The pixel-defining layer PDL may have openings associated with the respective emission areas and may surround the emission areas in a plan view. For example, the pixel-defining layer PDL may cover an edge of the first electrode ET1 of the light-emitting element ED, and may include an opening that exposes the remaining portion of the first electrode ET1. The area where the exposed portion of the first electrode ET1 and the emissive layer EML overlap each other may be the emission area of each pixel PX. According to an embodiment of the disclosure, the pixel-defining layer PDL may include at least one organic insulating layer including an organic insulating material.

The spacer SPC may be disposed on a part of the pixel-defining layer PDL. The spacer SPC may include at least one organic insulating layer including an organic insulating material. The spacer SPC and the pixel-defining layer PDL may include a same material or different materials. The pixel-defining layer PDL and the spacer SPC may be formed sequentially via the respective mask processes, or may be formed simultaneously and/or integrally using a halftone mask.

The encapsulation layer ENL may be disposed on the light-emitting element layer LEL. The encapsulation layer ENL may cover the light-emitting element layer LEL in the display area DA and may be extended to the non-display area NDA to be in contact with the panel circuit layer PCL. The encapsulation layer ENL may block the permeation of oxygen or moisture into the light-emitting element layer LEL and may alleviate electrical and/or physical shock on the panel circuit layer PCL and the light-emitting element LEL.

According to an embodiment of the disclosure, the encapsulation layer ENL may include a first encapsulation layer ENL1, a second encapsulation layer ENL2, and a third encapsulation layer ENL3 sequentially disposed on the light-emitting element layer LEL. Each of the first encapsulation layer ENL1 and the third encapsulation layer ENL3 may be an inorganic encapsulation layer including an inorganic material. The second encapsulation layer ENL2 may be an organic encapsulation layer including an organic material.

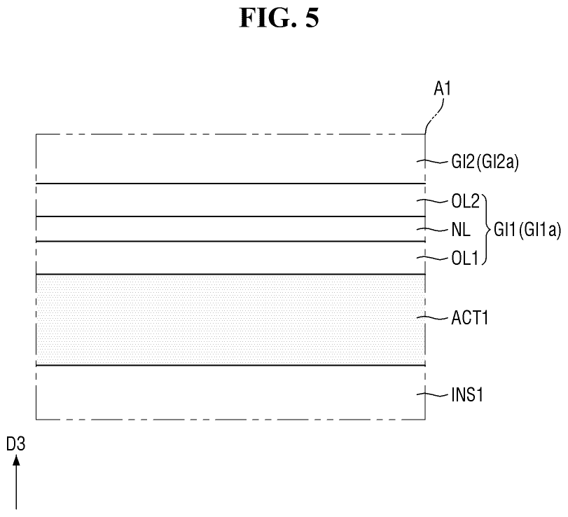

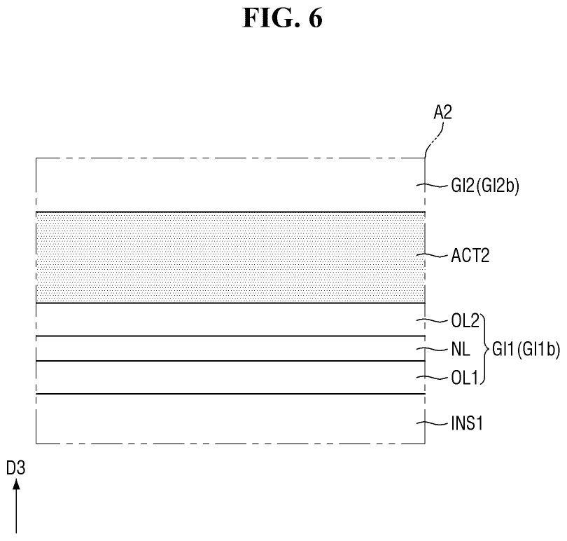

FIG. 5 is a schematic cross-sectional view showing area A1 of FIG. 4 in detail. FIG. 6 is a schematic cross-sectional view showing area A2 of FIG. 4 in detail. For example, FIGS. 5 and 6 are enlarged views showing the first gate insulating layer GI1 of FIG. 4 in detail.

Referring to FIGS. 5 and 6 in conjunction with FIG. 4, the first gate insulating layer GI1 may be a multi-layer insulating layer of three or more layers. For example, the first gate insulating layer GI1 may include multiple oxide layers including a first oxide layer OL1 and a second oxide layer OL2, and at least one nitride layer NL disposed between the oxide layers. The first oxide layer OL1, the nitride layer NL and the second oxide layer OL2 may overlap one another in the thickness direction of the gate insulating layer GI1, i.e., in the third direction D3.

According to an embodiment of the disclosure, the first gate insulating layer GI1 may be a triple layer including the first oxide layer OL1, the nitride layer NL on the first oxide layer OL1, and the second oxide layer OL2 on the nitride layer NL. According to another embodiment, the first gate insulating layer GI1 may consist of four or more layers that further includes at least one additional insulating layer in addition to the first oxide layer OL1, the nitride layer NL and the second oxide layer OL2.

The first oxide layer OL1 and the second oxide layer OL2 may be oxide-based insulating layers including hydrogen with different concentrations. According to an embodiment of the disclosure, among the first oxide layer OL1 and the second oxide layer OL2, the first oxide layer OL1 adjacent to the first active layer ACT1 having a first mobility (e.g., an oxide layer located in a lower layer of the first gate insulating layer GI1) may have a higher concentration of hydrogen than the second oxide layer OL2 adjacent to the second active layer ACT2 having a second mobility (e.g., an oxide layer located in an upper layer of the first gate insulating layer GI1). For example, the hydrogen concentration of the first oxide layer OL1 may be higher than the hydrogen concentration of the second oxide layer OL2. According to another embodiment, where the first active layer ACT1 is located higher than the first gate insulating layer GI1 while the second active layer ACT2 of high mobility is located lower than the first gate insulating layer GI2, the hydrogen concentration of an oxide layer located in an upper layer of the first gate insulating layer GI1 may be higher than the hydrogen concentration of an oxide layer located in a lower layer of the first gate insulating layer GI1.

According to an embodiment of the disclosure, each of the first oxide layer OL1 and the second oxide layer OL2 may be a silicon oxide layer including silicon oxide (SiOₓ). For example, the first oxide layer OL1 may be a high-hydrogen silicon oxide layer having a first hydrogen concentration, and the second oxide layer OL2 may be a low-hydrogen silicon oxide layer having a second hydrogen concentration lower than the first hydrogen concentration.

For example, in case that the hydrogen concentration of the first gate insulating layer GI1 is measured by secondary ion mass spectrometry (SIMS), the hydrogen concentration measured at the location where the first oxide layer OL1 is formed may be higher than the hydrogen concentration measured at the location where the second oxide layer OL2 is formed. According to an embodiment of the disclosure, the hydrogen concentration of the first oxide layer OL1 may be about 2.5 times or more than the hydrogen concentration of the second oxide layer OL2, but the disclosure is not limited thereto. For example, the hydrogen concentration of the first oxide layer OL1 may be about 3 times or more than the hydrogen concentration of the second oxide layer OL2.

By forming the first oxide layer OL1 as an oxide layer including high concentration of hydrogen (e.g., a high-hydrogen silicon oxide layer), the carrier concentration (e.g., electron concentration) of the first active layer ACT1 may be increased. Accordingly, trapping in the first active layer ACT1 may be reduced, and the reliability (e.g., positive bias temperature stress (PBTS) characteristics) of the first transistor T1 may be improved.

According to an embodiment of the disclosure, the characteristics of the first transistor T1 may be stabilized by controlling the film formation conditions of the first oxide layer OL1. For example, by forming the first oxide layer OL1 by low-power deposition, it may be possible to prevent or suppress the initial threshold voltage distribution of the first transistor T1 due to plasma damage to the first active layer ACT1. For example, by forming the first oxide layer OL1 by high-temperature deposition, it may be possible to reduce defects in the first oxide layer OL1 and to improve the reliability of the first transistor T1.

On the other hand, by forming the second oxide layer OL2 as an oxide layer including a low concentration of hydrogen (e.g., a low-hydrogen silicon oxide layer), it may be possible to control or limit the supply of hydrogen to the second active layer ACT2. Accordingly, it may be possible to prevent or suppress characteristic deviations and/or characteristic changes of the second transistor T2, such as distribution and change in the threshold voltage, and to improve the characteristics of the second transistor T2. For example, by limiting the supply of hydrogen to the second active layer ACT2 by the second oxide layer OL2, the operating characteristics of the second transistor T2 may become uniform and/or stabilized.

The nitride layer NL may include an insulating material suitable for functioning as a barrier that blocks diffusion of moisture or hydrogen between the first oxide layer OL1 and the second oxide layer OL2. For example, the nitride layer NL may be formed as a porous film and may trap and remove moisture introduced from the vicinity. Accordingly, the reliability of the first transistor T1 and the second transistor T2, as well as the circuit elements, the conductive patterns and/or the lines formed in the panel circuit layer PCL may be improved.

According to an embodiment of the disclosure, the nitride layer NL may include a silicon nitride layer including silicon nitride (SiNₓ), which may effectively block moisture or hydrogen. It should be noted that the material of the nitride layer NL is not limited thereto. The nitride layer NL may include other materials that can appropriately block moisture or hydrogen besides silicon nitride (SiNₓ).

According to the above-described embodiments, the first transistor T1 operating as the driving transistor DT of the pixel PX and the second transistor T2 operating as the switching transistor ST of the pixel PX may be formed of different types of oxide semiconductors with different characteristics. For example, the first oxide semiconductor of the first mobility (e.g., indium-gallium-zinc oxide (IGZO)) may form the first active layer ACT1 of the first transistor T1, and the second oxide semiconductor of the second mobility higher than the first mobility (e.g., indium-tin-gallium-zinc oxide (ITGZO) or indium-gallium oxide (IGO)) may form the second active layer ACT2 of the second transistor T2. In this manner, the characteristics of the first transistor T1 and the second transistor T2 may be improved to meet the operating characteristics required for each of the first transistor T1 and the second transistor T2. For example, the characteristics of the first transistor T1 and the second transistor T2 may be differentiated and/or optimized to satisfy the operating characteristics required for each of the first transistor T1 and the second transistor T2.

According to embodiments, the first gate insulating layer GI1 disposed on the first active layer ACT1 and under the second active layer ACT2 may be formed as three or more insulating layers including the first oxide layer OL1, the nitride layer NL and the second oxide layer OL2. The first oxide layer OL1 adjacent to the first active layer ACT1 may be formed as a high-hydrogen oxide layer (e.g., a high-hydrogen silicon oxide layer) that can supply hydrogen to the first active layer ACT1, and the second oxide layer OL2 adjacent to the second active layer ACT2 may be formed as a low-hydrogen oxide layer (e.g., a low-hydrogen silicon oxide layer) that can limit hydrogen flowing into the second active layer ACT2. The nitride layer NL interposed between the first oxide layer OL1 and the second oxide layer OL2 may be formed of a material (e.g., silicon nitride) that can effectively block moisture, hydrogen, etc. In this manner, the characteristics of the first transistor T1 and the second transistor T2 may be simultaneously improved and/or optimized, and the operating characteristics of the pixel PX including the first transistor T1 and the second transistor T2 and the display device 100 including the pixel PX may be improved.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first insulating layer disposed on a substrate;
a first transistor comprising a first active layer disposed on the first insulating layer and having a first mobility, and a first gate electrode overlapping the first active layer in a plan view;
a first gate insulating layer disposed on the first insulating layer and the first active layer;
a second gate insulating layer disposed on the first gate insulating layer; and
a second transistor comprising a second active layer disposed between the first gate insulating layer and the second gate insulating layer at a position spaced apart from the first active layer and having a second mobility greater than the first mobility, and a second gate electrode overlapping the second active layer in a plan view, wherein
the first gate insulating layer comprises a first oxide layer, a nitride layer on the first oxide layer, and a second oxide layer on the nitride layer, and
a hydrogen concentration of the first oxide layer is higher than a hydrogen concentration of the second oxide layer.

2. The display device of claim 1, wherein
the first active layer comprises a first oxide semiconductor, and
the second active layer comprises a second oxide semiconductor different from the first oxide semiconductor.

3. The display device of claim 2, wherein the first oxide semiconductor comprises indium-gallium-zinc oxide (IGZO).

4. The display device of claim 2, wherein the second oxide semiconductor comprises indium-tin-gallium-zinc oxide (ITGZO) or indium-gallium oxide (IGO).

5. The display device of claim 1, wherein the first oxide layer and the second oxide layer comprise silicon oxide.

6. The display device of claim 1, wherein the nitride layer comprises silicon nitride.

7. The display device of claim 1, wherein the first gate insulating layer comprises:
a first portion disposed on the first active layer; and
a second portion disposed between the first insulating layer and the second active layer.

8. The display device of claim 7, wherein the first gate insulating layer is partially disposed on a portion of the first active layer and a portion of the first insulating layer.

9. The display device of claim 7, wherein the second gate insulating layer comprises:
a first portion disposed on the first portion of the first gate insulating layer; and
a second portion disposed on the second active layer.

10. The display device of claim 1, wherein the second gate insulating layer is partially disposed on a portion of the first active layer and a portion of the second active layer.

11. The display device of claim 10, wherein the first gate electrode and the second gate electrode are disposed on the second gate insulating layer.

12. The display device of claim 1, wherein the second gate insulating layer comprises silicon oxide.

13. The display device of claim 1, wherein
the substrate comprises a display area, and
the first transistor and the second transistor are disposed in the display area.

14. The display device of claim 13, further comprising:
a pixel disposed in the display area and comprising the first transistor and the second transistor.

15. The display device of claim 14, wherein the first transistor is a driving transistor of the pixel.

16. The display device of claim 15, wherein the pixel further comprises a light-emitting element electrically connected to the first transistor.

17. The display device of claim 15, further comprising:
a bottom electrode disposed between the substrate and the first insulating layer and overlapping the first active layer in a plan view.

18. The display device of claim 14, wherein the second transistor is a switching transistor of the pixel.

19. The display device of claim 1, further comprising:
a second insulating layer that is disposed on the first insulating layer and covers the first active layer, the first gate insulating layer, the second active layer, the second gate insulating layer, the first gate electrode, and the second gate electrode.

20. The display device of claim 19, further comprising at least one of:
a first source electrode disposed on the second insulating layer and electrically connected to a source region of the first active layer;
a first drain electrode disposed on the second insulating layer and electrically connected to a drain region of the first active layer;
a second source electrode disposed on the second insulating layer and electrically connected to a source region of the second active layer; and
a second drain electrode disposed on the second insulating layer and electrically connected to a drain region of the second active layer.
